(19) United States
(12) Patent Application Publication
(10) Pub. No.: US 2010/0090204 A1
(43) Pub. Date: Apr. 15, 2010

(54) ORGANIC SEMICONDUCTOR ELEMENT AND MANUFACTURE METHOD THEREOF

(76) Inventors: Takashi Chuman, Saitama (JP); Chihiro Harada, Saitama (JP)

Correspondence Address: WENDEROTH, LIND & PONACK, L.L.P., 1030 15th Street, N.W.,, Suite 400 East, Washington, DC, 20005-1503, US

(21) Appl. No.: 12/450,315

(22) PCT Filed: Mar. 26, 2007
(86) PCT No.: PCT/JP2007/056212

§ 371 Date: Sep. 21, 2009

(51) Int. Cl. H01L 51/10; H01L 51/40

(52) U.S. Cl. 257/40; 257/57; 438/99; 438/158; 257/E51.006; 257/E51.001

(57) ABSTRACT

[Problems] To form an organic semiconductor layer more uniformly in a channel region by allowing formation of a pattern with a higher resolution in an organic semiconductor element.

[Solving Means] An organic semiconductor element includes a gate electrode 2 formed on a substrate 1, a gate insulating layer 3 formed on the gate electrode 2, a source electrode 4 and a drain electrode 5 formed on the gate insulating layer 3, and an organic semiconductor layer 6 placed between the source and drain electrodes 4 and 5 and opposite to the gate electrode 2 with the gate insulating layer 3 interposed therebetween. A barrier 7 is formed on the surfaces of the source and drain electrodes 4 and 5 at least except for a channel region formed between the source and drain electrode 4 and 5. The barrier 7 has a surface energy level lower than that of the channel region.

### TECHNICAL FIELD

The present invention relates to an organic semiconductor element and a manufacture method thereof.

### BACKGROUND ART

Organic TFTs (Thin Film Transistors), which are a type of organic semiconductor element, are manufactured by using an organic semiconductor material, so that the element can be reduced in weight and manufactured easily at a low temperature. The element can also have flexibility when a film material is used for a substrate thereof. In the organic TFT, an organic semiconductor layer is formed in a channel region between a pair of a source electrode and a drain electrode, and a gate electrode is opposed to the organic semiconductor layer in the channel region with a gate insulating layer interposed therebetween. In depositing the organic semiconductor material separately for each TFT, processing such as photolithography and etching is not preferable since the processing may deteriorate the organic semiconductor material due to heat or water. To address this, an organic semiconductor material of low molecular weight such as pentacene may be deposited by using a mask with a vacuum evaporation method or the like, for example. The vacuum evaporation method, however, involves complicated processing in order to perform the process under vacuum and a high cost resulting from the need for the mask having a high resolution. Therefore, the development of a coating application method is desired as a method which allows simple processing of the organic semiconductor material at an ordinary temperature.

In an inkjet method which is one of coating application methods, an organic semiconductor material in a liquid state can be used in ink form to perform patterning directly on a substrate and the processing can be performed at an ordinary temperature under an atmospheric pressure. In addition, since the pattern is directly formed on the substrate, no mask is required and material consumption can be reduced.

### DISCLOSURE OF THE INVENTION

### Problems to be Solved by the Invention

In forming the organic semiconductor layer with the coating application method such as the inkjet method, however, the following problems arise, by way of example.

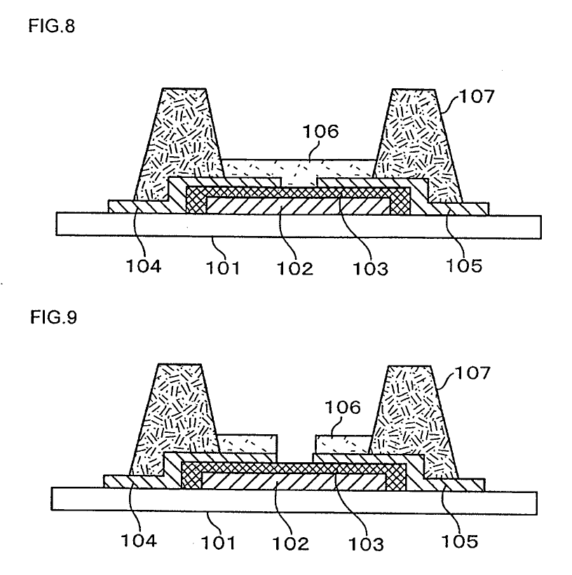

FIG. 8 shows an example of an organic TFT of a bottom contact type. The organic TFT shown in FIG. 8 includes a gate electrode 102, a gate insulating layer 103, a source electrode 104, and a drain electrode 105, all of which are formed sequentially on a substrate 101. The organic TFT also has an organic semiconductor layer 106 within a barrier 107 which surrounds a channel region. For forming the organic semiconductor layer with the inkjet method, a coating of an organic semiconductor material in ink form is applied to the materials having different surface energy levels, that is, the source and drain electrodes 104 and 105, and the gate insulating layer 103, within the barrier 107 surrounding the channel region. Thus, as shown in FIG. 9, the organic semiconductor material may be drawn onto the source and drain electrodes 104 and 105 having relatively high surface energy levels and the organic semiconductor layer 106 may not be formed on the gate insulating layer 103 or may be formed unevenly.

To improve the characteristics of the organic TFT, a known approach is to reduce surface energy levels by performing liquid-repellent treatment such as HMDL (Hexamethyldisilazane) treatment and OTS (Octadecyltrichlorosilane) treatment on the surface of the gate insulating layer. Such treatment may lead to a larger difference in the surface energy level between the source and drain electrodes and the gate insulating layer to cause the organic semiconductor material to be drawn toward the source and drain electrodes, with the result that the uneven organic semiconductor layer tends to be formed.

It is thus an object of the present invention to form an organic semiconductor layer more uniformly in a channel region by allowing formation of a pattern with a higher resolution.

### Means for Solving the Problems

According to an aspect, as described in claim 1, the present invention provides an organic semiconductor element including a substrate, a gate electrode, a gate insulating layer, a source electrode and a drain electrode, and an organic semiconductor layer placed between the source electrode and the drain electrode and opposite to the gate electrode with the gate insulating layer interposed between the organic semiconductor layer and the gate electrode, wherein a covering layer is formed on surfaces of the source electrode and the drain electrode at least except for a channel region formed between the source electrode and the drain electrode, the covering layer having a surface energy level lower than that of the channel region.

According to another aspect, as described in claim 8, the present invention provides a method of manufacturing an organic semiconductor element including a substrate, a gate electrode, a gate insulating layer, a source electrode and a drain electrode, and an organic semiconductor layer placed between the source electrode and the drain electrode and opposite to the gate electrode with the gate insulating layer interposed between the organic semiconductor layer and the gate electrode, including the steps of forming a covering layer on surfaces of the source electrode and the drain electrode at least except for a channel region formed between the source electrode and the drain electrode, the covering layer having a surface energy level lower than that of the channel region, and forming the organic semiconductor layer in the channel region.

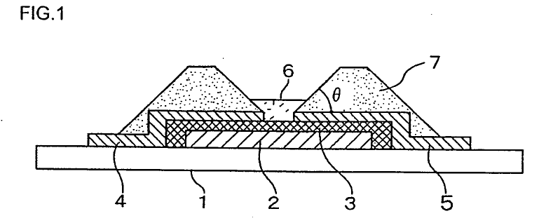

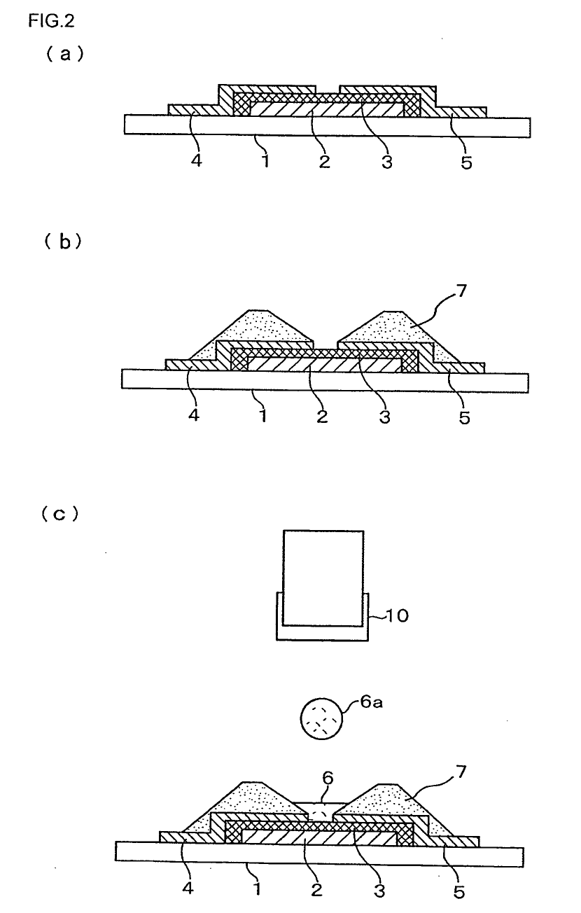

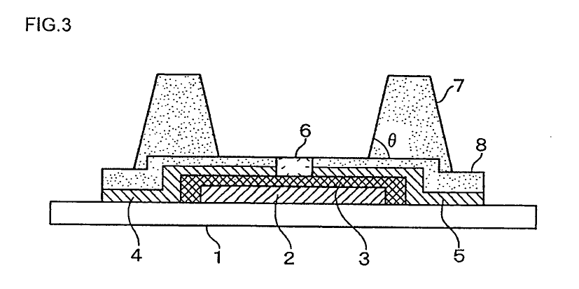

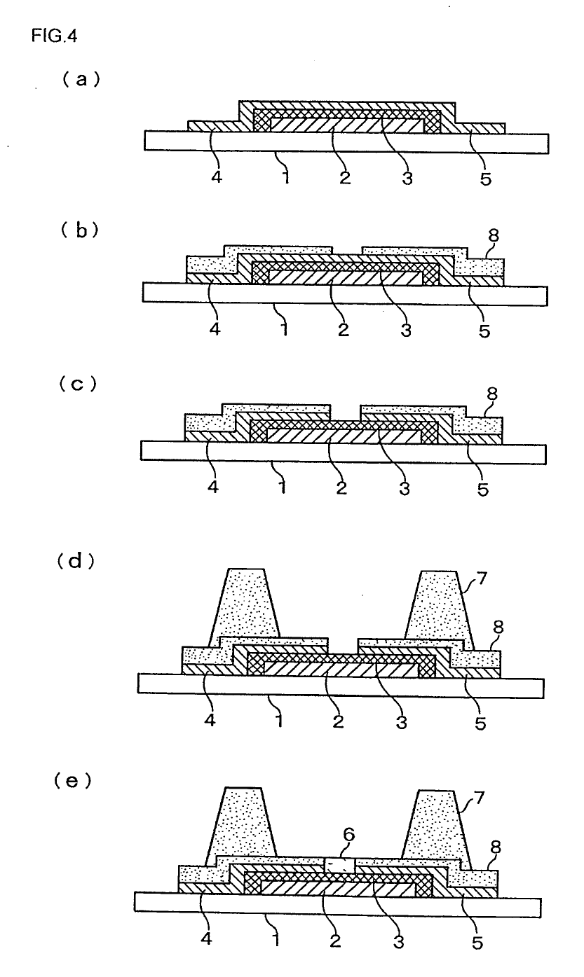

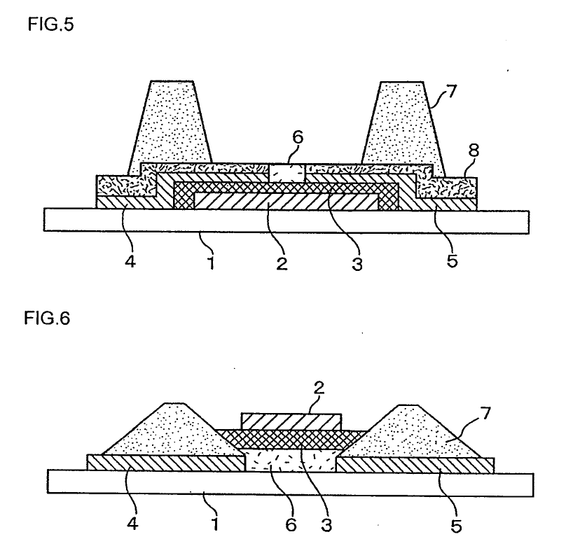

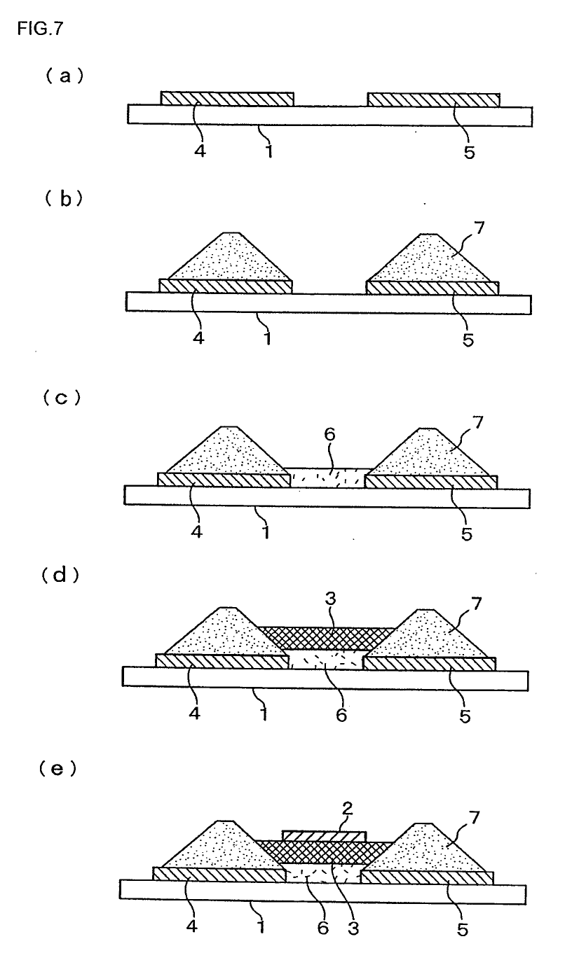

### BRIEF DESCRIPTION OF DRAWINGS

[FIG. 1] A section view schematically showing an organic TFT according to Embodiment 1 of the present invention.

[FIG. 2] Diagrams for explaining a method of manufacturing the organic TFT shown in FIG. 1.

[FIG. 3] A section view schematically showing an organic TFT according to Embodiment 2 of the present invention.

[FIG. 4] Diagrams for explaining a method of manufacturing the organic TFT shown in FIG. 2.

[FIG. 5] A section view schematically showing an organic TFT according to Embodiment 3 of the present invention.

[FIG. 6] A section view schematically showing an organic TFT according to Embodiment 4 of the present invention.

[FIG. 7] Diagrams for explaining a method of manufacturing the organic TFT shown in FIG. 6.

[FIG. 8] A section view schematically showing an organic TFT for explaining the problem to be addressed by the present invention.

[FIG. 9] A section view schematically showing an organic TFT for explaining the problem to be addressed by the present invention.

### DESCRIPTION OF REFERENCE NUMERALS

1 SUBSTRATE
2 GATE ELECTRODE
3 GATE INSULATING LAYER
4 SOURCE ELECTRODE
5 DRAIN ELECTRODE
6 ORGANIC SEMICONDUCTOR LAYER
6a INK-FORM ORGANIC SEMICONDUCTOR MATERIAL
7 BARRIER
8 COVERING FILM
10 INKJET HEAD
101 SUBSTRATE
102 GATE ELECTRODE
103 GATE INSULATING LAYER
104 SOURCE ELECTRODE
105 DRAIN ELECTRODE
106 ORGANIC SEMICONDUCTOR LAYER
107 BARRIER

### BEST MODE FOR CARRYING OUT THE INVENTION

Embodiments according to the present invention will hereinafter be described with reference to the drawings. The present invention is not limited to the illustration in the following description.

### Embodiment 1

FIG. 1 is a section view schematically showing an organic TFT of a bottom contact type as Embodiment 1 of an organic semiconductor element corresponding to the present invention.

The organic TFT shown in FIG. 1 has a gate electrode 2 formed on a substrate 1, a gate insulating layer 3 formed on the gate electrode 2, a source electrode 4 and a drain electrode 5 formed on the gate insulating layer 3, and an organic semiconductor layer 6 made of an organic semiconductor material such as P3HT (poly-3-hexylthiophene) and placed between the source and drain electrodes 4 and 5 such that the layer 6 is opposite to the gate electrode 2 with the gate insulating layer 3 interposed therebetween.

The organic TFT has a barrier 7 which lies on the surfaces of the source and drain electrodes 4 and 5 except for a channel region formed between the source and drain electrodes 4 and 5. The barrier 7 serves as a covering layer which has a surface energy level lower than that of the channel region. The barrier 7 is formed to the edge of the channel region, defies the area where the organic semiconductor layer 6 is formed, and in supply of an organic semiconductor material in a liquid state to the channel region, prevents the organic semiconductor material from dispersing or flowing out. In addition, the barrier 7 can avoid electrical interference between the adjacent elements.

The barrier 7 has the surface energy level lower than those of the gate insulating layer 3 in the channel region and of the source and drain electrodes 4 and 5, and the surface of the barrier 7 has the property of repelling a liquid readily. The barrier 7 is preferably made of a material having insulation and liquid repellency such as a fluororesin, for example.

In this manner, the source and drain electrodes 4 and 5 having relatively high surface energy levels and tending to attracting a liquid are covered with the barrier 7 having the lower surface energy level, thereby providing a low surface energy level to repel a liquid. This allows the gate insulating layer 3 having a relatively low surface energy level and tending to repel a liquid to have a high surface energy level relatively to that of the barrier 7. Since the organic semiconductor material in the liquid state is drawn onto the gate insulating layer 3 in the channel region, the organic semiconductor layer 6 can be formed uniformly.

Since the organic semiconductor material supplied to the channel region is surrounded by the barrier 7 having the low surface energy level in the channel region, the material is not drawn to the surroundings from the channel region. As a result, the organic semiconductor layer 6 can be maintained uniformly on the gate insulating layer 3.

In the supply of the organic semiconductor material in the liquid state to the channel region, the organic semiconductor material contacts the barrier 7 but is repelled thereby and supplied concentratedly to the channel region. Thus, an appropriate amount of the organic semiconductor material can be used to form the organic semiconductor layer 6 uniformly.

Even when liquid-repellent treatment such as HMDS treatment and OTS treatment for improving the characteristics of the organic TFT is performed on the surface of the gate insulating layer 3 to cause a larger difference in the surface energy level between the gate insulating layer 3 and the source and drain electrodes 4 and 5, the barrier 7 covering the surfaces of the source and drain electrodes 4 and 5 can reduce the surface energy level. This enables the uniform formation of the organic semiconductor layer 6 on the gate insulating layer 3 in the channel region.

While the barrier 7 has a normally tapered shape and has an inclination angle θ of approximately 40° in the example shown in FIG. 1, the shape is not particularly limited thereto, and another shape may be used such as a rectangular shape depending on the process or the uses. The inclination angle θ of the barrier 7 is not limited to 40° but is adjustable in a range from 20° to 90°. The thickness of the barrier 7 is not particularly limited and is adjustable in a range from 100 nm to 10 μm. When the barrier 7 covers the source electrode 4 and drain electrode 5 to their end portions closer to the channel as shown in the example shown in FIG. 1, a larger inclination angle θ reduces the area (opening area) where the material in ink form is dropped, so that the inclination angle is preferably set to approximately 40°.

FIGS. 2(a) to 2(c) are diagrams for explaining a method of manufacturing the organic TFT in Embodiment 1.

As shown in FIG. 2(a), the gate electrode 2, the gate insulating layer 3, and the source and drain electrodes 4 and 5 are deposited in order on the substrate 1. For example, a glass substrate is used as the substrate 1, and Cr is deposited as the gate electrode 2 on the substrate 1 and patterned with a wet etching method. SiO₂ is formed as the gate insulating layer 3 on the gate electrode 2. Next, a stacked film of Cr/Au is formed as the source and gate electrodes 4 and 5 on the gate insulating layer 3 and patterned with the wet etching method.

Next, as shown in FIG. 2(b), the barrier 7 is formed on the surfaces of the source and drain electrodes 4 and 5 to cover the electrodes 4 and 5 to the edge portion of the channel region except for the channel region. For example, a photosensitive fluororesin is deposited as the barrier 7 and patterned with photolithography. When a positive-type resist fluororesin is used, light is diffused toward a bottom surface of the barrier 7 during exposure, and in removal, the portion exposed to the diffused light is retained to pattern the barrier 7 into the shape gradually widened toward the bottom surface. This results in the barrier 7 having the normally tapered shape. The tapered angle θ can be adjusted by the exposure time or the intensity.

Then, as shown in FIG. 2(c), a coating of the organic semiconductor material in the liquid state is applied to the channel region surrounded by the barrier 7 with the inkjet method to form the organic semiconductor layer 6 in the channel region. For example, the organic semiconductor material 6 in ink form is applied from an inkjet head 10 which is positioned to the channel region. The printing of the organic semiconductor material in ink form can be performed by using a polymer organic semiconductor material such as P3HT. An organic semiconductor material of low molecular weight can also be printed in ink form by using a precursor or the like which can be solved in a solvent. The coating application method of the semiconductor material in the liquid state is not limited to the inkjet method, and another method can be used such as coating application with the use of a dispenser.

According to the manufacture method as described above, since the surface energy level of the barrier 7 is lower than that of the channel region, the organic semiconductor layer 6 can be formed uniformly on the gate insulating layer 3 in the channel region. The organic semiconductor material contacts the barrier 7 but is repelled thereby and supplied to the channel region, so that an appropriate amount of the organic semiconductor material can be used to form the organic semiconductor layer 6 uniformly. In addition, since the channel region is surrounded by the barrier 7, the organic semiconductor layer 6 can be maintained uniformly.

### Embodiment 2

FIG. 3 is a section view schematically showing an organic TFT as Embodiment 2 of the organic semiconductor element corresponding to the present invention. Components identical to those in Embodiment 1 described above are designated with the same reference numerals, and description of common structures is omitted.

The organic TFT shown in FIG. 3 has a gate electrode 2 formed on a substrate 1, agate insulating layer 3 formed on the gate electrode 2, a source electrode 4 and a drain electrode 5 formed on the gate insulating layer 3, and an organic semiconductor layer 6 made of an organic semiconductor material such as P3HT in a channel region between the source and drain electrodes 4 and 5.

A covering film 8 is formed on the surfaces of the source and drain electrodes 4 and 5 except for the channel region and serves as a film portion of a covering layer having a surface energy level lower than that of the channel region. The covering film 8 is formed to the edge portion of the channel region to cover the surfaces of the source and drain electrodes 4 and 5. The covering film 8 has the surface energy level lower than those of the gate insulating layer 3 in the channel region and of the source and drain electrodes 4 and 5, and the surface of the film 8 has the property of repelling a liquid readily. The covering film 8 is preferably made of a material having insulation and liquid repellency such as a fluororesin, for example.

In this manner, the source and drain electrodes 4 and 5 having relatively high surface energy levels and tending to attracting a liquid are covered with the covering film 8 having the lower surface energy level, thereby providing a low surface energy level to repel a liquid. This allows the gate insulating layer 3 having a relatively low surface energy level and tending to repel a liquid to have a high surface energy level relatively to that of the covering film 8. An organic semiconductor material in a liquid state is drawn to the channel region to enable the uniform formation of the organic semiconductor layer 6.

The covering film 8 can also be used as a mask in patterning the source and drain electrodes 4 and 5. In such a case, the source and drain electrodes 4 and 5 are formed over the entire surface, the covering film 8 is formed except for the area corresponding to the channel region, and the covering film 8 is used as the mask to perform the patterning by removing the portions of the source and drain electrodes 4 and 5 in the channel region. This can provide the shape in which the covering film 8 and the source and drain electrodes 4 and 5 have the aligned edges. Since the covering film 8 is used as part of the element and thus does not need to be removed, it is possible to omit a process corresponding to a conventional mask removal process.

A barrier 7 serving as a barrier portion of the covering layer is formed of the same material as that of the covering film 8 to surround the channel region. When the organic semiconductor material in the liquid state is supplied to the channel region, the barrier 7 prevents the organic semiconductor material from dispersing or flowing out. Since the covering film 8 is formed to the edge portion of the channel region, the surface energy level near the edge portion of the channel region can be held low even when the edge portion of the barrier 7 does not coincide with the edge portion of the channel region. Also, the area surrounded by the barrier 7 can be widened due to the presence of the covering film 8, which can widen the area where the material in ink form is dropped. This can realize the barrier 7 having a large inclination angle θ of approximately 70° as shown in FIG. 3.

FIGS. 4(a) to 4(e) are diagrams for explaining a method of manufacturing the organic TFT in Embodiment 2.

As shown in FIG. 4(a), the gate electrode 2 and the gate insulating layer 3 are deposited in order on the substrate, and the source and drain electrodes 4 and 5 are deposited over the entire surface of the gate insulating layer 3.

Next, as shown in FIG. 4(b), the covering film 8 is formed on the source and drain electrodes 4 and 5 except for the area corresponding to the channel region. Then, as shown in FIG. 4(c), the covering film 8 is used as a mask to pattern the source and drain electrodes 4 and 5 to form the channel region. For example, a stacked film of Cr/Au is used for the source and drain electrodes 4 and 5, a fluororesin is used as the covering film 8 and patterned to open the channel region, and the covering film 8 is used as the mask to perform the patterning by removing the portions of the source and drain electrodes 4 and 5 with the wet etching method.

Next, as shown in FIG. 4(d), the barrier 7 is formed on the covering film 8 to surround the channel region. The barrier 7 is made of the same material as that of the covering film 8 and can be formed to have a normally tapered shape by using a positive-type resist fluororesin as described above. Since the covering film 8 is formed to the edge portion of the channel region, the end portion of the barrier 7 does not need to be matched with the edge portion of the channel region.

Then, as shown in FIG. 4(e), a coating of the organic semiconductor material in the liquid state is applied to the channel region with the inkjet method to form the organic semiconductor layer 6. In the coating application to the channel region, the organic semiconductor material contacts the covering film 8 and the barrier 7 but is repelled thereby due to the low surface energy level and is collected to the channel region having the relatively high surface energy level. Thus, an appropriate amount of the organic semiconductor material is supplied to the channel region, and the organic semiconductor layer 6 can be formed uniformly therein.

### Embodiment 3

FIG. 5 is a section view schematically showing an organic TFT as Embodiment 3 of the organic semiconductor element corresponding to the present invention. Components identical to those in Embodiments 1 and 2 described above are designated with the same reference numerals, and description of common structures is omitted.

In Embodiment 2 described above, the same material is used for the covering film 8 and the barrier 7. In Embodiment 3, however, different materials are used for a covering film 8 and a barrier 7. The remaining structure can be realized by using the same structure as that in Embodiment 2.

In Embodiment 3, the covering film 8 is formed on the surfaces of a source electrode 4 and a drain electrode 5 to the edge portion of a channel region except for the channel region. The barrier 7 is formed of a material different from that of the covering film 8. For example, different fluororesins can be used for the covering film 8 and the barrier 7.

Thus, for example when the material appropriate for the covering film 8 is preferably different from the material appropriate for the barrier 7 in view of the film thickness after coating application, the resolution and the like, the different materials appropriate for the covering film 8 and the barrier 7 can be used.

### Embodiment 4

FIG. 6 is a section view schematically showing an organic TFT of a top gate type as Embodiment 4 of the organic semiconductor element corresponding to the present invention. Components identical to those in Embodiments 1 to 3 described above are designated with the same reference numerals, and description of common structures is omitted.

The organic TFT shown in FIG. 6 includes a source electrode 4 and a drain electrode 5 formed on a substrate 1, a barrier 7 having a surface energy level lower than that of a channel region and formed on the surfaces of the source and drain electrodes 4 and 5 to the edge portion of the channel region except for the channel region, an organic semiconductor layer 6 formed in the channel region surrounded by the barrier 7 and made of an organic semiconductor material such as P3HT, a gate insulating layer 3 formed on the organic semiconductor layer 6 in the area surrounded by the barrier 7, and a gate electrode 2 formed on the gate insulating layer 3.

The barrier 7 has the surface energy level lower than those of the substrate 1 in the channel region and of the source and drain electrodes 4 and 5, and the surface of the barrier 7 has the property of repelling a liquid readily. The barrier 7 is preferably made of a material having insulation and liquid repellency such as a fluororesin, for example.

In this manner, the source and drain electrodes 4 and 5 having relatively high surface energy levels and tending to attracting a liquid are covered with the barrier 7 having the lower surface energy level, thereby providing a low surface energy level to repel a liquid. This allows the substrate 1 in the channel region to have a high surface energy level relatively to that of the barrier 7. An organic semiconductor material in a liquid state is drawn onto the substrate 1 in the channel region, so that the organic semiconductor layer 6 can be formed uniformly.

Since the organic semiconductor material supplied to the channel region is surrounded by the barrier 7 having the low surface energy level in the channel region, the material is not drawn to the surroundings from the channel region. As a result, the organic semiconductor layer 6 can be maintained uniformly on the substrate 1.

In the supply of the organic semiconductor material in the liquid state to the channel region, the organic semiconductor material contacts the barrier 7 but is repelled thereby and supplied concentratedly to the channel region. Thus, an appropriate amount of the organic semiconductor material can be used to form the organic semiconductor layer 6 uniformly.

In forming the gate insulating layer 3 on the organic semiconductor layer 6, the barrier 7 can define the area where the gate insulating layer 3 is formed.

In the structure of the organic TFT of the top gate type described above, an overlap is small between the source and drain electrodes 4 and 5 and the gate electrode 2 in a vertical direction, and the insulating barrier 7 is present in the overlap. This can reduce a parasitic capacitance which is produced between the electrodes to deteriorate the element characteristics.

FIGS. 7(a) to 7(e) are diagrams for explaining a method of manufacturing the organic TFT in Embodiment 4.

As shown in FIG. 7(a), the source and drain electrodes 4 and 5 are formed on the substrate 1. Next, as shown in FIG. 7(b), the barrier 7 is formed on the surfaces of the source and drain electrodes 4 and to the edge portion of the channel region except for the channel region. The liquid barrier 7 can have a normally tapered shape by using a positive-type resist fluororesin as described above.

Then, as shown in FIG. 7(c), the organic semiconductor material in the liquid state is supplied to the channel region surrounded by the barrier 7 to form the organic semiconductor layer 6. Since the surface energy level of the barrier 7 is lower than that of the substrate 1 in the channel region, the organic semiconductor layer 6 can be formed uniformly on the substrate 1 in the channel region. The organic semiconductor material in the liquid state contacts the barrier 7 but is repelled thereby and collected to the channel region 6. In the channel region 6, the organic semiconductor material is not drawn to the surroundings of the channel region due to the low surface energy level of the barrier 7, so that the organic semiconductor layer 6 can be formed uniformly.

Then, as shown in FIG. 7(d), the gate insulating layer 3 is formed on the organic semiconductor layer 6. The gate electrode 2 is formed on the gate insulating layer 3 as shown in FIG. 7(e).

The material of the covering layer in the present invention is not limited to the abovementioned fluororesin. An organic material or an inorganic material may be used as long as the material has a surface energy level lower than that of the channel region, and those materials may be stacked. While the patterning of the covering layer can be performed with the photolithography by using the photosensitive resin as described above, the present invention is not limited thereto and a dry process can be used such as dry etching. The formation of the covering layer is not limited to the use of the material having the low surface energy level, and the covering layer may be formed of an insulating material into a desired shape and then surface treatment may be performed thereon to reduce the surface energy level.

The covering layer in the present invention may be formed on the surfaces of the source and drain electrodes at least except for the channel region. Even when the covering layer does not cover the surfaces of the source and drain electrodes to the edge portion of the channel region, the effects of the present invention can be provided by forming the covering layer on part of the surface of the source and drain electrodes opposite to the organic semiconductor material around the channel region.

The organic semiconductor layer in the present invention is not limited to the abovementioned P3HT but any organic material exhibiting semiconductor properties may be used. The ink form is desirable so that it can be used in the coating application method, and an organic semiconductor material in a liquid state or an organic semiconductor material soluble in a solvent may be used. For example, it is possible to use a polymer material having a structure used in a main chain of a polymer such as a polyethylene chain, a polysiloxane chain, a polyether chain, a polyester chain, a polyamide chain, and a polyimide chain, or bound in pendant form as a side chain, or a carbon-based conjugate polymer such as an aromatic conjugated polymer including polyparaphenylene, an aliphatic conjugated polymer including polyacetylene, a heterocyclic conjugated polymer including polypinole and polythiophene or the like, a heteroatom-containing conjugated polymer including polyaniline and polyphenylene sulfide, and a composite conjugated polymer having a structure of alternately bonded constituent units of a conjugated polymer including poly(phenylenevinylene), poly(arylenevinylene) and poly(thienylenevinylene). It is also possible to use a polymer including alternate chains of oligosilane and a carbon-based conjugated structure such as polysilane and a disilanylene carbon-based conjugated polymer structure including a disilanylene arylene polymer and a (disilanylene) ethynylene polymer. In addition, it is possible to use a polymer chain including an inorganic element containing phosphorous or nitrogen, a polymer containing a coordinated aromatic ligand of a polymer chain such as phthalocyanate polysiloxane, a polymer containing ring-fused perylene with thermal treatment such as perylenetetracarboxylic acid, a ladder polymer obtained by thermally treating a polyethylene derivative containing a cyano group such as polyacrylonitrile, and a composite material containing an intercalated organic compound in perovskite. It is also possible to use a material of low molecular weight soluble in a solvent by adding a functional group, among a phthalocyanine derivative, a naphthalocyanine derivative, an azo compound derivative, a perylene derivative, an indigo derivative, a quinacridone derivative, a polycyclic quinone derivative such as anthraquinone, a cyanine derivative, a fullerene derivative, or a nitrogen-containing cyclic compound derivative such as indole, carbazole, oxazole, inoxazole, thiazole, imidazole, pyrazole, oxaadiazole, pyrazoline, thiathiazole, and triazole, a hydrazine derivative, a triphenylamine derivative, a triphenylmethane derivative, stilbene, a quinone compound derivative such as anthraquinone diphenoquinone, and a polycyclic aromatic compound derivative such as anthracene, bilene, phenanthrene, and coronene.

The gate insulating layer in the present invention is not limited to the abovementioned SiO₂, and any inorganic material or organic material may be used as the gate insulating layer as long as the material has insulation. For example, it is possible to use effectively a metal oxide such as LiOx, LiNx, NaOx, KOx, RbOx, CsOx, BeOx, MgOx, MgNx, CaOx, CaNx, SrOx, BaOx, ScOx, YOx, YNx, LaOx, LaNx, CeOx, PrOx, NdOx, SmOx, EuOx, GdOx, TbOx, DyOx, HoOx, ErOx, TmOx, YbOx, LuOx, TiOx, TiNx, ZrOx, ZrNx, HfOx, HfNx, ThOx, VOx, VNx, NbOx, TaOx, TaNx, CrOx, CrNx, MoOx, MoNx, WOx, WNx, MnOx, ReOx, FeOx, FeNx, RuOx, OsOx, CoOx, RhOx, Irox, NiOx, PdOx, PtOx, CuOx, CuNx, AgOx, AuOx, ZnOx, CdOx, HgOx, BOx, BNx, AlOx, AlNx, GaOx, GaNx, InOx, TiOx, TiNx, SiNx, GeOx, SnOx, PbOx, POx, PNx, AsOx, SbOx, SeOx, and TeOx, a metal composite oxide such as LiAlO₂, Li₂SiO₃, Li₂TiO₃, Na₂Al₂₂O₃₄, NaFeO₂, Na₄SiO₄, K₂SiO₃, K₂TiO₃, K₂WO₄, Rb₂CrO₄, Cs₂CrO₄, MgAl₂O₄, MgFe₂O₄, MgTiO₃, CaTiO₃, CaWO₄, CaZrO₃, SrFe₁₂O₁₉, SrTiO₃, SrZrO₃, BaAl₂O₄, BaFe₁₂O₁₉, BaTiO₃, Y₃A₁₅O₁₂, Y₃Fe₅O₁₂, LaFeO₃, La₃Fe₅O₁₂, La₂Ti₂O₇, CeSnO₄, CeTiO₄, Sm₃Fe₆O₁₂, EuFeO₃, Eu₃Fe₆O₁₂, GdFeO₃, Gd₃Fe₅O₁₂, DyFeO₃, Dy₃Fe₆O₁₂, HoFeO₃, Ho₃Fe₆O₁₂, ErFeO₃, Er₃Fe₆O₁₂, Tm₃Fe₅O₁₂, LuFeO₃, Lu₃Fe₅O₁₂, NiTiO₃, Al₂TiO₃, FeTiO₃, BaZrO₃, LiZrO₃, MgZrO₃, HfTiO₄, NH₄VO₃, AgVO₃, LiVO₃, BaNb₂O₆, NaNbO₃, SrNb₂O₆, KTaO₃, NaTaO₃, SrTa₂O₆, CuCr₂O₄, Ag₂CrO₄, BaCrO₄, K₂MoO₄, Na₂MoO₄, NiMoO₄, BaWO₄, Na₂WO₄, SrWO₄, MnCr₂O₄, MnFe₂O₄, MnTiO₃, MnWO₄, CoFe₂O₄, ZnFe₂O₄, FeWO₄, CoMoO₄, CuTiO₃, CuWO₄, Ag₂MoO₄, Ag₂WO₄, ZnAl₂O₄, ZnMoO₄, ZnWO₄, CdSnO₃, CdTiO₃, CdMoO₄, CdWO₄, NaAlO₂, MgAl₂O₄, SrAl₂O₄, Gd₃Ga₅O₁₂, InFeO₃, MgIn₂O₄, Al₂TiO₅, FeTiO₃, MgTiO₃, Na₂SiO₃, CaSiO₃, ZrSiO₄, K₂GeO₃, Li₂GeO₃, Na₂GeO₃, Bi₂Sn₃O₉, MgSnO₃, SrSnO₃, PbSiO₃, PbMoO₄, PbTiO₃, SnO₂—Sb₂O₃, CuSeO₄, Na₂SeO₃, ZnSeO₃, K₂TeO₃, K₂TeO₄, Na₂TeO₃, and Na₂TeO₄, a sulfide such as FeS, Al₂S₃, MgS, and ZnS, a fluoride such as LiF, MgF₂, and SmF₃, a chloride such as HgCl, FeCl₂, and CrCl₃, a bromide such as AgBr, CuBr, and MnBr₂, an iodide such as PbI₂, CuI, and FeI₂, or a metal oxynitride such as SiAlON. The gate insulating layer may be formed by anodizing the gate electrode. For example, Ta, Al, Mg, Ti, Nb, or Zr alone or an alloy thereof is effectively used. A polymer material is also effectively used such as polyimide, polyamide, polyester, polyacrylate, epoxy resin, phenol resin, and polyvinyl alcohol. As described above, the surface of the gate insulating layer may be subjected to the liquid-repellent treatment such as HMDS treatment and OTS treatment.

The gate electrode, the source electrode, and the drain electrode in the present invention are not limited to Cr as the gate electrode or Cr/Au as the source electrode and drain electrode described above, and any material having sufficient conductivity may be used. For example, it is possible to use metal alone such as Pt, Au, W, Ru, Ir, Al, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, and Lu, a compound thereof, or a stack thereof. It is also possible to use a metal oxide such as ITO (Indium Tin Oxide) and IZO (Indium Zinc Oxide), or an organic conductive material containing a conjugate polymer compound such as polyaniline, polythiophene, and polypyrrole.

The organic semiconductor element according to the present invention includes the substrate, the gate electrode, the gate insulating layer, the source electrode and the drain electrode, and the organic semiconductor layer placed between the source electrode and the drain electrode and opposite to the gate electrode with the gate insulating layer interposed therebetween, wherein the covering layer is formed on the surfaces of the source electrode and the drain electrode at least except for the channel region formed between the source electrode and the drain electrode, the covering layer having the surface energy level lower than that of the channel region.

The method of manufacturing the organic semiconductor element according to the present invention is the method of manufacturing the organic semiconductor element including the substrate, the gate electrode, the gate insulating layer, the source electrode and the drain electrode, and the organic semiconductor layer placed between the source electrode and the drain electrode and opposite to the gate electrode with the gate insulating layer interposed therebetween, including the steps of forming the covering layer on the surfaces of the source electrode and the drain electrode at least except for the channel region formed between the source electrode and the drain electrode, the covering layer having the surface energy level lower than that of the channel region, and forming the organic semiconductor layer in the channel region.

According to the present invention described above, the organic semiconductor layer can be formed more uniformly in the channel region by allowing the formation of the pattern with a higher resolution.

### EXAMPLES

Examples of the present invention will hereinafter be described. The present invention is not limited by those Examples.

### Example 1

In Example 1, the organic transistor shown in FIG. 1 was produced and its characteristics were evaluated.

The organic TFT had a channel length and a channel width equal to 5 μm and 300 μm, respectively. A glass substrate was used as the substrate 1, and Cr was deposited and patterned as the gate electrode 2 on the substrate 1. Cr had the film thickness of 100 nm, and the patterning was performed with the wet etching method. Next, SiO₂ was formed as the gate insulating layer 3 to have a thickness of 200 nm on the gate electrode 2. A stacked film of Cr/Au was formed to have 5 nm/100 nm, respectively, as the source and drain electrodes 4 and 5 on the gate insulating layer 3. The patterning of the source and drain electrodes 4 and 5 was performed with the wet etching method. Then, a fluororesin (PMA-#702, manufactured by CHISSO PETROCHEMICAL CORPORATION) was patterned as the barrier 7 to the edge portion of the channel region except for the channel region. The barrier 7 had a normally tapered shape such that its end portion lay at the edge portion of the channel region. The barrier 7 had a height of approximately 4 μm and a tapered angle of approximately 40°. Next, P3HT was deposited as the organic semiconductor layer 6 to have a thickness of approximately 100 nm with the inkjet method to produce the organic TFT element. The evaluation of the TFT characteristics of the element showed the favorable characteristics of mobility: 0.03 cm²/Vs, threshold voltage: −2.0 V, and on/off: 10⁵.

### Example 2

In Example 2, the organic transistor shown in FIG. 3 was produced and its characteristics were evaluated.

The organic TFT had a channel length and a channel width equal to 5 μm and 300 μm, respectively. A glass substrate was used as the substrate 1, and Cr was deposited and patterned as the gate electrode 2 on the substrate 1. Cr had the film thickness of 100 nm, and the patterning was performed with the wet etching method. Next, SiO₂ was formed as the gate insulating layer 3 to have a thickness of 200 nm on the gate electrode 2. A stacked film of Cr/Au was formed to have 5 nm/100 nm, respectively, as the source and drain electrodes 4 and 5 on the gate insulating layer 3. Then, a fluororesin (PMA-#702, manufactured by CHISSO PETROCHEMICAL CORPORATION) was patterned as the covering film 8 into the shapes of the source and drain electrodes 4 and 5, and the covering film 8 was used as a mask to pattern the source and drain electrodes 4 and 5 with the wet etching method. With the covering film 8 remaining, the barrier 7 was patterned with the same fluororesin as the covering film 8 to surround the channel region. The barrier 7 had a normally tapered shape and was formed to be opened more widely than the channel region. The barrier 7 had a height of approximately 4 μm and a tapered angle of approximately 70°. Next, P3HT was deposited as the organic semiconductor layer 6 to have a thickness of approximately 100 nm with the inkjet method to produce the organic TFT element. The evaluation of the TFT characteristics of the element showed the favorable characteristics of mobility: 0.04 cm²/Vs, threshold voltage: −1.5 V, and on/off: 10⁵.

### Example 3

In Example 3, the organic transistor shown in FIG. 5 was produced and its characteristics were evaluated.

The organic TFT had a channel length and a channel width equal to 5 μm and 300 μm, respectively. A glass substrate was used as the substrate 1, and Cr was deposited and patterned as the gate electrode 2 on the substrate 1. Cr had the film thickness of 100 nm, and the patterning was performed with the wet etching method. Next, SiO₂ was formed as the gate insulating layer 3 to have a thickness of 200 nm on the gate electrode 2. A stacked film of Cr/Au was formed to have 5 nm/100 nm, respectively, as the source and drain electrodes 4 and 5 on the gate insulating layer 3. Then, a fluororesin (PMA-#802, manufactured by CHISSO PETROCHEMICAL CORPORATION) was patterned as the covering film 8 into the shapes of the source and drain electrodes 4 and 5, and the covering film 8 was used as a mask to pattern the source and drain electrodes 4 and 5 with the wet etching method. With the covering film 8 remaining, the barrier 7 was patterned with a fluororesin (PMA-#702, manufactured by CHISSO PETROCHEMICAL CORPORATION) different from the covering film 8 to surround the channel region. The barrier 7 had a normally tapered shape and was formed to be opened more widely than the channel region. The barrier 7 had a height of approximately 4 μm and a tapered angle of approximately 70°. Next, P3HT was deposited as the organic semiconductor layer 6 to have a thickness of approximately 100 nm with the inkjet method to produce the organic TFT element. The evaluation of the TFT characteristics of the element showed the favorable characteristics of mobility: 0.04 cm²/Vs, threshold voltage: −2.0 V, and on/off: 10⁵.

### Example 4

In Example 3, the organic transistor shown in FIG. 6 was produced and its characteristics were evaluated.

The organic TFT had a channel length and a channel width equal to 5 gm and 300 μm, respectively. A glass substrate was used as the substrate 1, and a stacked film of Cr/Au was formed to have 5 nm/100 nm, respectively, as the source and drain electrodes 4 and 5 on the substrate 1. The patterning of the source and drain electrodes 4 and 5 was performed with the wet etching method. Next, a fluororesin (PMA-#702, manufactured by CHISSO PETROCHEMICAL CORPORATION) was patterned as the barrier 7 to be formed except for the channel region. The barrier 7 had a normally tapered shape such that the end portion of the barrier 7 lay at the edge portion of the channel region. The barrier 7 had a height of approximately 4 μm and a tapered angle of approximately 40°. P3HT was deposited as the organic semiconductor layer 6 in the area surrounded by the barrier 7 to have a thickness of approximately 100 nm with the inkjet method. SiO₂ was formed as the gate insulating layer 3 to have a thickness of 200 nm on the organic semiconductor layer 6. Next, Cr was deposited and patterned as the gate electrode 2. Cr had a thickness of 100 nm and the patterning was performed with the wet etching method. The evaluation of the TFT characteristics of the element showed the favorable characteristics of mobility: 0.02 cm²/Vs, threshold voltage: +1.0 V, and on/off: 10⁵.

1. An organic semiconductor element comprising a substrate, a gate electrode, a gate insulating layer, a source electrode and a drain electrode, and an organic semiconductor layer placed between the source electrode and the gate electrode and opposite to the gate electrode with the gate insulating layer interposed between the organic semiconductor layer and the gate electrode,
wherein a covering layer is formed on surfaces of the source electrode and the drain electrode at least except for a channel region formed between the source electrode and the drain electrode to an edge portion of the channel region, the covering layer having a surface energy level lower than a surface energy level of the channel region.

2. (canceled)

3. The organic semiconductor element according to claim 1, wherein the covering layer has a barrier shape which surrounds the channel region.

4. The organic semiconductor element according to claim 1, wherein the covering layer includes a film portion which covers the surfaces of the source electrode and the drain electrode and a barrier portion which surrounds the channel region.

5. The organic semiconductor element according to claim 4, wherein the film portion and the barrier portion are made of different materials.

6. The organic semiconductor element according to claim 1, wherein the gate electrode, the gate insulating layer, the source electrode and the drain electrode, and the covering layer are stacked in order over the substrate, and the organic semiconductor layer is provided in the channel region.

7. The organic semiconductor element according to claim 1, wherein the source electrode and the drain electrode, and the covering layer are stacked in order over the substrate, the organic semiconductor layer is provided in the channel region, and the gate insulating layer and the gate electrode are stacked in order over the organic semiconductor layer.

8. A method of manufacturing an organic semiconductor element including a substrate, a gate electrode, a gate insulating layer, a source electrode and a drain electrode, and an organic semiconductor layer placed between the source electrode and the gate electrode and opposite to the gate electrode with the gate insulating layer interposed between the organic semiconductor layer and the gate electrode, comprising the steps of:
forming a covering layer on surfaces of the source electrode and the drain electrode at least except for a channel region formed between the source electrode and the drain electrode, to an edge portion of the channel region, the covering layer having a surface energy level lower than a surface energy level of the channel region, and forming the organic semiconductor layer in the channel region.

9. The method of manufacturing an organic semiconductor element according to claim 8, wherein the organic semiconductor layer is formed with an inkjet method.

10. The method of manufacturing an organic semiconductor element according to claim 8, wherein the covering layer is used as a mask when the source electrode and the drain electrode are formed.
